(19) United States
(12) Patent Application Publication
(10) Pub. No.: US 2024/0369665 A1
(43) Pub. Date: Nov. 7, 2024

(54) ISOLATED TEST AND MEASUREMENT PROBE

(71) Applicant: Tektronix, Inc., Beaverton, OR (US)

(72) Inventors: Daniel G. Knierim, Beaverton, OR (US); Noah Brummer, Portland, OR (US); Roger D. Bighouse, Canby, OR (US)

(21) Appl. No.: 18/652,163

(22) Filed: May 1, 2024

Related U.S. Application Data
(60) Provisional application No. 63/463,994, filed on May 4, 2023.

(51) Int. Cl. G01R 35/00; G01R 1/067; G01R 13/02

(52) U.S. Cl. CPC G01R 35/00; G01R 1/06766; G01R 13/0218

(57) ABSTRACT

A test and measurement accessory has an input to receive an input signal from a device under test (DUT), a pilot signal generator to generate a pilot signal, an E/O converter to convert the input signal and the pilot signal to a combined optical signal, an O/E converter to convert the combined optical signal to a combined electrical signal, a signal separator to separate the pilot signal from the combined electrical signal, an amplitude detector to determine amplitude of the separated pilot signal, and circuitry to adjust a gain of a signal path using the amplitude. A test and measurement accessory has an input to receive an input signal from a DUT, an E/O converter to produce an optical signal, an optical splitter to split the optical signal into a feedback portion and a remaining portion, a feedback photodiode to produce a feedback electrical signal to adjust the optical signal.

### CROSS-REFERENCE TO RELATED APPLICATIONS

This disclosure is a non-provisional of and claims benefit from U.S. Provisional Application No. 63/463,994, titled “ISOLATED TEST AND MEASUREMENT PROBE,” filed on May 4, 2023, the disclosure of which is incorporated herein by reference in its entirety.

### TECHNICAL FIELD

This disclosure relates to test and measurement instruments and probes, and more particularly to an isolated test and measurement probe.

### BACKGROUND

A test and measurement probe connects a test and measurement instrument, such as an oscilloscope (“scope”), to a device under test (DUT) for testing and/or measuring one or more signals from the DUT. An isolated test and measurement probe, such as one of the TIVP family of probes made by Tektronix, uses galvanic (e.g., optical) or RF isolation to divorce the reference voltage of the probe from the reference voltage of the oscilloscope (typically Earth Ground). This enables power designers to accurately resolve high bandwidth, high voltage differential signals in the presence of large common mode voltages. Tektronix isolated probes employ IsoVu™ Probe Technology that uses galvanic isolation to provide best in class common mode rejection performance across a wide bandwidth in a small probe form factor.

The combination of isolation and high frequency in IsoVu™ probes provide power designers with more accurate measurements than traditional differential probes for applications that require high bandwidth while measuring high voltage signals. Example uses of this approach include: switched mode power supply design; power field effect transistor (FET) design/analysis for wide bandgap gallium arsenide (GaN) and silicon carbide (SiC) devices; inverter design; motor Drive design; bulk current injection (BCI) or electrostatic discharge (ESD) measurements; and current shunt measurements.

Existing isolated probes have a built-in calibration routine to compensate signal path gain and offset errors that may be introduced due to drift, often temperature-induced drift. The optical components, such as distributed feedback (DFB) laser with its back-facet monitor diode, optical fiber, and photodiode, are responsible for a majority of this drift. It is not convenient for the probe user to have to rerun the calibration routine frequently to correct minor thermally induced errors in these components.

U.S. Pat. No. 9,557,399 discloses a low-frequency (LF) offset-correction technique involving digitizing the input signal at low speed, digitizing the output signal at low speed, transmitting one of the digital signals across the isolation barrier on another fiber, comparing the digitized values to determine an error, and feeding this error signal back (FB) or forward (FF) to correct the LF error. This works well on the LF offset errors but cannot correct LF gain errors mixed up to high-frequency (HF) sidebands. Another approach, uses a faster local feedback scheme sensing the optical output of the electrical to optical converter (E/O) that converts the electrical signal to an optical signal, comparing the optical output with the input signal, and adjusting the laser drive accordingly. This does not correct gain modulation sidebands on HF signals and suffers from thermally induced LF gain errors in the “back-facet monitor” used to sense the optical output from the laser.

### BRIEF DESCRIPTION OF THE DRAWINGS

FIG. 1 shows a test and measurement accessory in between a device under test (DUT) and a test and measurement instrument.

FIG. 2 shows an embodiment of a test and measurement accessory employing a pilot signal to adjust a signal.

FIG. 3 shows an embodiment of a test and measurement accessory employing a front light feedback signal to adjust a signal.

FIG. 4 shows an embodiment of a test and measurement accessory employing a differential optical signal.

### DETAILED DESCRIPTION

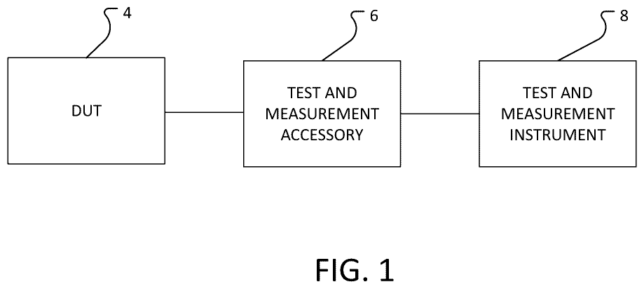

Embodiments disclosed herein include multiple aspects to improve the performance of isolated probe technology. An isolated probe may comprise at least a part of a test and measurement accessory. As shown in FIG. 1, a test and measurement instrument 8, such as an oscilloscope, gathers data from device under test (DUT) 4. The test and measurement accessory 6 resides in the path between the DUT and the instrument. Improving the performance of the test and measurement accessory improves the accuracy of the data received at the instrument compared to the original data from the DUT.

One embodiment uses a pilot tone to sense the gain variation directly, separate from any low frequency (LF) offset error. Prior approaches sense overall LF error but cannot separate LF offset error from LF gain error multiplied by LF signal content. By sensing the gain error separately, one can independently correct the gain error, including the HF sidebands, and still use prior approaches to correct any remaining LF offset error.

Another embodiment uses differential signaling. A test and measurement accessory receives a single-ended or differential electrical signal from the DUT and converts it into a differential optical signal using two lasers. The compensation unit receives the two optical signals and converts them into a single-ended or differential electrical signal. An amplifier in the compensation unit may be employed to amplify the signal and/or convert to single-ended format before being sent to the test and measurement instrument, such as an oscilloscope. The differential approach, to the extent the two sides are matched, allows separation and automatic cancellation of offset errors, which show up as common mode. This makes the gain errors easier to track and adjust. The differential approach provides additional benefits as well, such as the cancelation of any other common errors and the averaging of independently random errors between the two sides.

Another embodiment uses a photodiode external to the DFB laser. The external photodiode provides a simpler and more directed approach to solve the LF gain variation resulting from the thermally induced changes in the light reaching the monitor diode, due to power dissipation changes in the laser. This decouples the laser and the monitor diode thermally by placing them in different packages, so heat generated by the laser does not impact the feedback correction scheme.

Another embodiment involves using a silicon photonics substrate for either “side” of the optical fiber, either alone or in combination with any of the other embodiments. The photonics substrate lowers costs and enables local thermal feedback to maintain constant temperature to prevent thermally induced errors from occurring. Any of the below approaches, or their combination(s) can compensate for the signal path gain and/or offset errors.

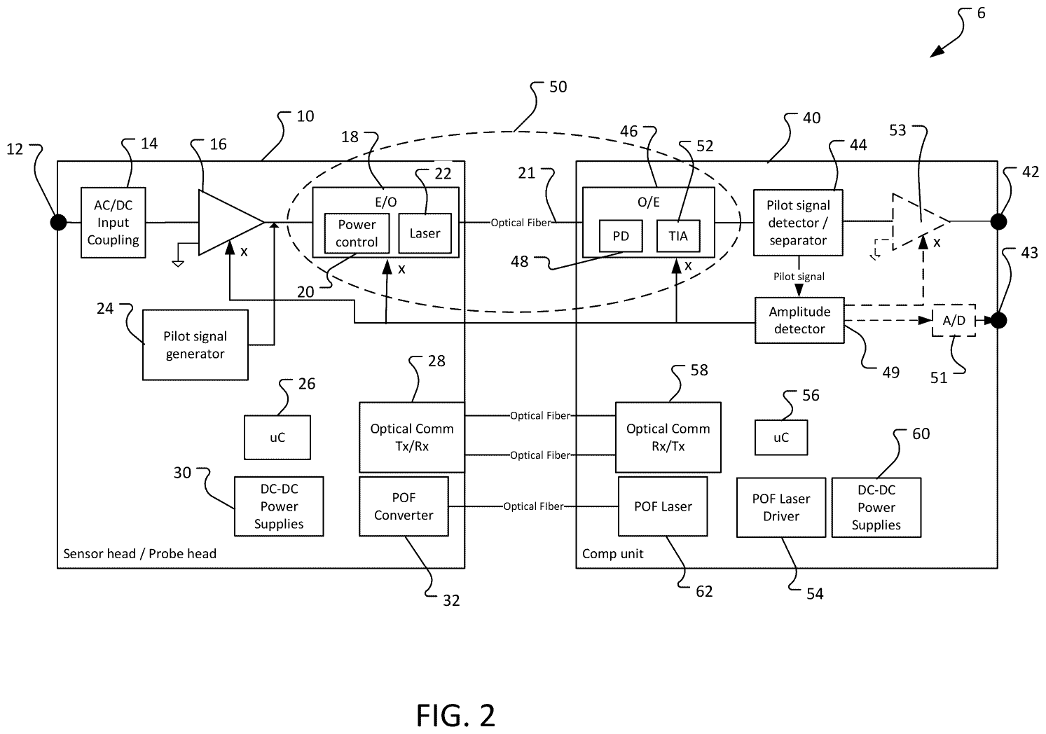

FIG. 2 shows an embodiment of a test and measurement accessory used to collect data from a device under test (DUT) that employs a pilot signal. As mentioned above, using a pilot signal senses the gain variation directly. In FIG. 1, the test and measurement accessory 6 has an input 12 to receive an electrical signal from the DUT. The electrical signal undergoes AC/DC input coupling at 14, and amplifier 16 amplifies the signal. An electrical to optical converter (E/O) converter 18 will convert the input signal to an optical signal. The electrical to optical converter 18 will generally have a power control 20 that controls power used by the laser 22 to produce the optical signal. The E/O converter 18 will also receive an electrical pilot signal from pilot signal generator 24, discussed in more detail below. The E/O 18 converter will combine the pilot signal and the input signal to produce and transmit a combined optical signal from laser 222 through an optical fiber 21 to the optical to electrical (O/E) converter 46. The O/E converter has a light sensor, typically a photodiode 48, and typically includes a transimpedance amplifier (TIA) 52. In the embodiments here, the E/O converter 18 may reside on a sensor or probe head 10, and the O/E converter may reside on a compensation unit 40, but other configurations are possible.

The resulting signal from the O/E converter is a combined electrical signal. A pilot signal detector/separator 44 separates the pilot signal from the electrical signal that would ideally be the original electrical signal received from the DUT sent to the output 42. However, as discussed above, different effects in the signal path between the input 12 and the output 42 alter the resulting signal. The pilot signal allows the test and measurement accessory to correct for those effects. The alteration may result from thermal drift in region 50 of FIG. 2, often from the heating of the lasers as they operate and/or mechanical motion of the optical fiber.

The components in the lower portion of the test and measurement accessory provide operational control of the sensor/probe head 10 and its communication with the compensation unit 40. These include microcontrollers 26 and 56, DC-DC power supplies, 30 and 60, optical communications transmit and receive components 28 and 58, power over fiber (POF) converter 32 and laser 62, with the associated laser driver 54. These will typically comprise standard components and are included here for completeness.

The pilot signal generator 24 may generate one of many different types of pilot signals. In an embodiment, the pilot signal comprises an out-of-band signal added to the input signal prior to conversion to an optical signal. On the receiving end, the pilot signal detector/separator 44 may comprise a diplexer to separate out the pilot signal to produce a separated pilot signal and an output electrical signal. The separator 44 then sends the pilot signal to the amplitude detector 49. The amplitude detector 49 detects the amplitude of the pilot signal and includes circuitry to provide an adjustment signal to adjust the gain of the signal path between the input 12 and the output 42. The gain adjustment may comprise a positive or a negative adjustment.

The adjustment may take the form of a feedback signal, sent back to the input amplifier 16, to adjust the input signal to account for the gain difference, sent to the E/O converter to adjust the power applied to the laser 22 by power unit 20, or the electrical signal to be converted and sent to the O/E converter to adjust its operation. Alternatively, an optional output amplifier 53 could receive the output of the amplitude detector 49, and adjust the resulting signal sent to the output 42. The components and paths in the figures that have dashed lines show alternative embodiments, or optional components.

In another embodiment, the amplitude of the separated pilot signal could be sent to the test and measurement instrument in addition to the output electrical signal. The test and measurement instrument can correct the signal received from the test accessory using the amplitude of the separated pilot signal. The amplitude of the separated pilot signal may be sent to the test and measurement instrument through a different output 43 than the output electrical signal sent through the output 42. In an embodiment, the combined electrical signal, comprising the pilot signal and the output electrical signal, would be sent to the instrument and the instrument would perform the separation, amplitude detection and gain adjustment. Variations include having the signal separator on the test and measurement accessory, and the amplitude detection being part of the test and measurement instrument, or the amplitude detector could reside on the test and measurement accessory and its output may be converted by an analog-to-digital converter (A/D) 51 prior to the output 43 to send the amplitude digitally to the test and measurement instrument. The different output 43 would allow either the pilot signal or the amplitude to be sent. In these variations, the first output 42 would send at least the output electrical signal to the test and measurement instrument.

In an alternative to the out-of-band pilot signal, the pilot signal could comprise a pseudo random sequence inserted into the input signal by the pilot signal generator. On the receiving end, the pilot signal detector/separator 44 would include a signal generator to generate the same sequence. The separator 44 would then look for maximum correlation between the inserted pattern and the one generated in the compensation unit. This would allow detection of the phase and the amplitude of the sequence and subtraction from the combined signal by the amplitude detector 49 to send the feedback or feedforward signal as above.

In another alternative, the input signal could be modulated onto a carrier signal separate from the pilot signal generated by the pilot signal generator 24. The pilot signal separator 44 would then demodulate the two signals to separate them, allowing the pilot signal to reach the amplitude detector.

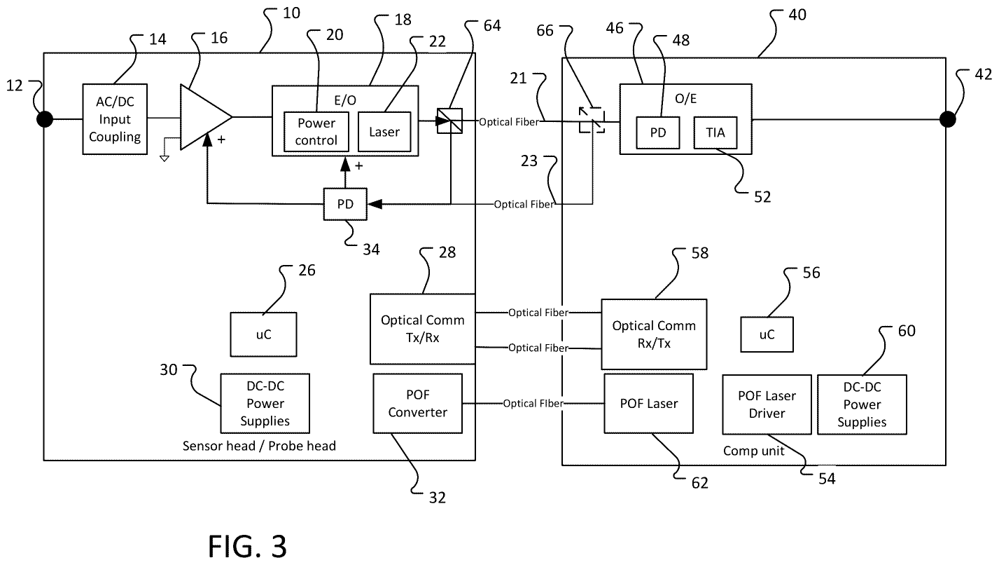

Another approach uses a portion of the optical signal as a feedback signal, as shown in FIG. 3. Existing optically isolated probes use an optical signal from an optical signal source, such as the lasers shown here, to convey a representation of the signal under test from the DUT. Existing probes use the electrical signal from a monitor photodiode mounted within the E/O package such as 18 in FIG. 3 at the back-facet mirror in order to track and adjust the output optical signal in a low-frequency feedback loop. Unfortunately, the tracking error of the monitor photodiode to the main optical output changes with the temperature of the laser 22, which in turn changes with the applied input signal. This leads to non-linear and somewhat hysteretic errors in the optical output as the feedback loop works to stabilize the monitor diode current, not necessarily the optical output power.

Embodiments herein, such as the one shown in FIG. 3, replace the back-facet mirror with a separate optical splitter 64 and a feedback photodiode 34 external to, and separate from, the E/O converter 18. The majority of the optical power still passes down the cable to the receiver in the compensation unit, maintaining good SNR for the high-bandwidth path, but a small amount is picked off in the probe head for a local O/E conversion and slower feedback loop. In contrast to the previously discussed approach of using the back-facet, this approach uses “front” light coming from the E/O laser. In one embodiment, the optical splitter may reside either on the probe head 10 as shown at 64, or on the compensation unit 40 as shown at 66. This may provide more room and/or better temperature control for the splitter. The splitter could also reside at a midway point in the fiber 21, and an additional fiber 23 routed back to the probe head for the feedback photodiode 34.

The electrical feedback signal from photodiode 34 could be used in the same manner as the back-facet monitor diode's signal is currently used, simplifying implementation. The external, separate photodiode may transmit the signal to the amplifier 16 and or the E/O converter 18. In either case, the effect is an additive effect rather than the multiplicative effect of embodiments such as that shown in FIG. 2.

Lasers are often used for optical transport of RF signals, wherein the signal encoding is already expected to deal with gain modulation due to moving antennas and/or reflectors in a multi-path environment. This makes the lasers relatively immune to the thermal impact on tracking error in the back-facet diode. The front light approach separates the optical splitting and photo-detection from the thermal dissipation of the laser itself, thereby minimizing this thermally induced tracking error for applications, such as broad-band oscilloscope probes, which are sensitive to such slower modulation effects.

Another embodiment takes advantage of differential signaling. The optical path from probe head to compensation unit in existing optically isolated probes is single-ended in nature and suffers from many of the same errors found in single-ended electrical signal paths, such as even-order distortions, noise, power-supply sensitivity, to name a few.

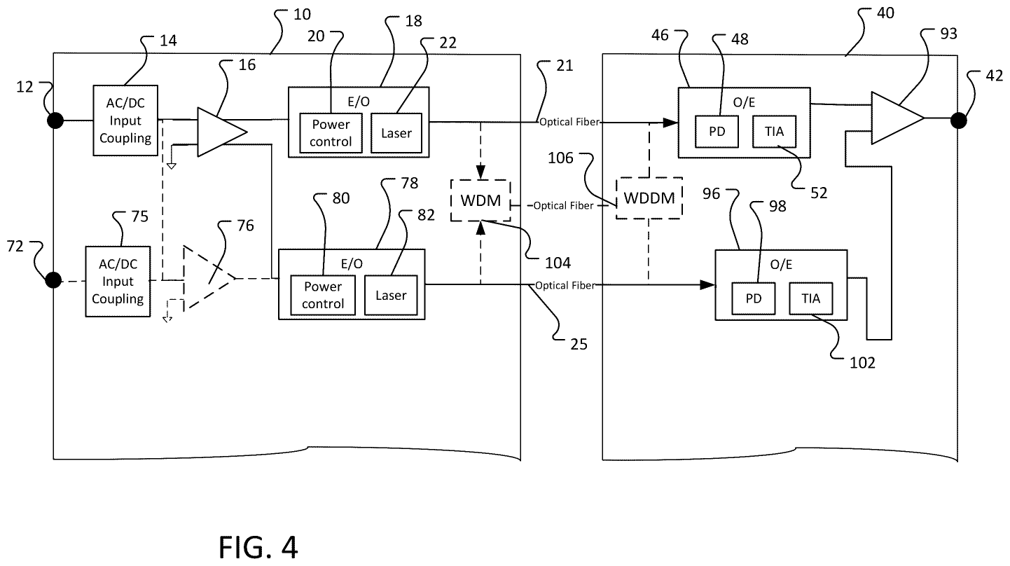

According to some embodiments of the disclosure, one can make the optical path differential by using two lasers, as shown in FIG. 4, as E/O converters 18 and 78. E/O converter 78 would have its own power control 89 and laser 82. The amplifier 16 in this embodiment may comprise an amplifier having differential outputs. Each of the E/O converters is driven by one side of the differential output of amplifier 16. The configuration in this embodiment may comprise two optical signal fibers, 21 and 25, and two photodiodes 48 and 98 of O/E converters 46 and 96 in the compensation unit 40. The formation of the differential signal could occur at other points of the input path, such as before the input amplifier 16, which may include a second input amplifier 76. The first part of the input signal would travel one path to be converted to a first optical signal by E/O converter 18, and the second part of the input signal would travel the other path to be converted to a second optical signal by E/O converter 78 having a separate power control 80 and laser 82 than the E/O convert 18, with the second optical signal from the E/O converter 78 having an amplitude that varies in opposite polarity to the first optical signal.

The control components have been removed from this figure for simplification but would still exist in this embodiment.

According to other embodiments of the disclosure, Wavelength Division Multiplexing (WDM) 104 may be employed to pass output of both lasers down a single fiber and separate them again to the two photodiodes using a Wavelength Division DeMultiplexer (WDDM) 106. The amplifier 93 in the compensation unit 40 can then recombine these into a single-ended electrical output 42 to the oscilloscope if desired. Each O/E converter 46 and 96 has a TIA 52 and 102, but an alternative includes there being one TIA instead of amplifier 93, to combine the two signals.

Although this differential approach adds cost for the extra laser and photodiode, it serves to cancel several single-ended errors, such as even-order distortion, common-mode supply and temperature sensitivity, and averages by a factor of two other, more random, errors, such as Schott noise and hysteretic thermal distortion. Another alternative could use differential signals from the DUT, as shown by input 72 on the lower path, with additional amplifier 76 and AC/DC coupling 75.

Another embodiment involves implementing isolation technology with integrated electronics and optics, i.e., using silicon photonics.

Physical space and power are both at a premium in an optically isolated probe head such as the Tektronix TIVP family of isolated probes. Smaller size allows closer placement to the DUT, which reduces CMRR loss due to cable braid resistance, and also reduces the “capacitance-to-infinity” of the probe body, which reduces DUT loading and further improves CMRR. Meanwhile, electrical power to run the probe head is supplied optically, which is not efficient and complicates probe safety requirements.

Combining electrical and optical components on the same die, or a co-packaged die using 2.5D and 3D techniques will be referred to here as a photonics substrate. The photonics substrate intends to remove the space and power barriers to die-to-die communication that currently limits the Moore's Law growth of computing. These same techniques can be used to produce a “single chip” optically isolated probe head, with perhaps a few functions, such as the O/E power converter/laser on a separate die and/or package.

Many features that might be too expensive to implement separately may become practical with the benefits of integration on a single chip. These include input multiplexing, such as to measure either high-side V_{gs} or high-side Iₛ, differential optical signaling, localized heaters to “ovenize” critical temperature-sensitive devices, thermometers with controllable temperature elements such as the localized heaters or other components to regulate temperature, additional local feedback loops for error correction, and pilot-tone insertion for continuous calibration, such as discussed above.

Current silicon photonics research is focused on high-speed serial communication, such as for use in the data center. Use in an isolated probe head represents a new and non-competing use for the same basic technology. It can enable putting many more optical devices in the probe head, but also is limited to the device selection available on the chosen technology. However, that selection can be expected to increase over time as the technology is refined and adopted in data centers.

In the embodiment of FIG. 2, this might, for instance, result in the pilot signal generator and the E/O converter residing on a first photonics substrate, represented by the probe head substrate 10, and the O/E converter, the signal separator, and the amplitude detector residing on a second photonics substrate represented by the compensation unit substrate 40, the first and second photonics substrates being optically coupled by the fiber. As mentioned above, the laser components, the E/O converters and the O/E converters may be adjacent to the photonics substrates, but for the purposes of this discussion will be referred to as residing on the separate substrates.

In the embodiment of FIG. 4, this might, for instance, result in the first E/O converter and the second E/O converter residing on a first photonics substrate, the first O/E converter, the second O/E converter, and the amplifier residing on a second photonics substrate, the first photonics substrate and the second photonics substrate optically coupled by one or more optical fibers.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement accessory, comprising: an input to receive an input electrical signal from a device under test (DUT); a pilot signal generator to generate a pilot signal; an electrical to optical (E/O) converter coupled to the input and the pilot signal generator to convert the input electrical signal and the pilot signal to a combined optical signal; a fiber to transmit the combined optical signal; an optical to electrical (O/E) converter to receive the combined optical signal and convert the combined optical signal to a combined electrical signal; a signal separator to separate the pilot signal from the combined electrical signal; an amplitude detector to receive the separated pilot signal from the signal separator and determine an amplitude of the separated pilot signal; and circuitry to adjust a gain of a signal path from the input to a test and measurement instrument using the amplitude of the separated pilot signal.

Example 2 is the test and measurement accessory of Example 1, wherein the pilot signal generator produces an out-of-band pilot signal.

Example 3 is the test and measurement accessory of Example 2, wherein the signal separator comprises a diplexer to separate the out-of-band pilot signal from the combined electrical signal.

Example 4 is the test and measurement accessory of any of Examples 1 through 3, wherein the pilot signal comprises a pseudo-random sequence.

Example 5 is the test and measurement accessory of Example 4, further comprising: a second signal generator to generate a matching pseudo-random sequence; and circuitry configured to determine a correlation between the combined electrical signal and the matching pseudo-random sequence.

Example 6 is the test and measurement accessory of any of Examples 1 through 5, wherein the E/O converter modulates the input electrical signal onto a carrier signal distinct from the pilot signal.

Example 7 is the test and measurement accessory of any of Examples 1 through 6, wherein the pilot signal generator and the E/O converter reside on a first photonics substrate, and the O/E converter, the signal separator, and the amplitude detector reside on a second photonics substrate, the first and second photonics substrates being optically coupled by the fiber.

Example 8 is the test and measurement accessory of any of Examples 1 through 7, wherein the circuitry to adjust the gain of the signal path from the input to the test and measurement instrument transmits a signal based upon the amplitude of the separated pilot signal back to the E/O converter.

Example 9 is the test and measurement accessory of any of Examples 1 through 8, wherein the circuitry to adjust the gain of the signal path from the input to the test and measurement instrument transmits a signal based upon the amplitude of the separated pilot signal back to the O/E converter.

Example 10 is the test and measurement accessory of any of Examples 1 through 9, wherein the circuitry to adjust the gain of the signal path from the input to the test and measurement instrument transmits a signal based upon the amplitude of the separated pilot signal back to an input amplifier electrically coupled to the input.

Example 11 is the test and measurement accessory of any of Examples 1 through 10, wherein the circuitry to adjust the gain of the signal path from the input to the test and measurement instrument transmits a signal based upon the amplitude of the separated pilot signal forward to an output amplifier.

Example 12 is the test and measurement accessory of any of Examples 1 through 11, wherein the signal separator is structured to produce the separated pilot signal and an output electrical signal.

Example 13 is the test and measurement accessory of Example 12, further comprising an output to send the output electrical signal to the test and measurement instrument.

Example 14 is a test and measurement accessory, comprising: an input to receive an electrical signal from a device under test (DUT); an electrical to optical (E/O) converter coupled to the input to convert the electrical signal to an optical signal; an optical splitter separate from the E/O converter to split the optical signal into a feedback portion of the optical signal and a remaining portion of the optical signal; a fiber to transmit the remaining portion of the optical signal; a feedback photodiode to generate a feedback signal from the feedback portion of the optical signal and produce a feedback electrical signal to the E/O converter to adjust the optical signal; and an O/E converter to receive the remaining portion of the optical signal to convert the remaining portion of the optical signal to an electrical signal.

Example 15 is the test and measurement accessory of Example 14, wherein the optical splitter resides on a probe head with the E/O and the input.

Example 16 is the test and measurement accessory of either of Examples 14 or 15, wherein the optical splitter resides with the O/E converter, and the test and measurement accessory further comprises a second optical fiber to route the feedback portion back to a probe head containing the E/O and the input.

Example 17 is the test and measurement accessory of any of Examples 14 through 16, wherein the E/O converter receives the feedback signal through an amplifier to adjust an output of the amplifier based upon the feedback portion.

Example 18 is the test and measurement accessory of any of Examples 14 through 17, wherein the E/O converter receives the feedback signal to adjust the operation of the E/O converter.

Example 19 is a test and measurement accessory, comprising: an input to receive an input electrical signal from a device under test (DUT); a pilot signal generator to generate a pilot signal; an electrical to optical (E/O) converter coupled to the input and the pilot signal generator to convert the input electrical signal and the pilot signal to a combined optical signal; a fiber to transmit the combined optical signal; an optical to electrical (O/E) converter to receive the combined optical signal and convert the combined optical signal to a combined electrical signal comprised of the pilot signal and an output electrical signal; and an output to send at least the output electrical signal to a test and measurement instrument.

Example 20 is the test and measurement accessory of Example 19, further comprising a signal separator to separate the combined electrical signal into the output electrical signal and the pilot signal, and a second output to allow the test and measurement accessory to send the pilot signal to the test and measurement instrument.

Example 21 is the test and measurement accessory of either of Examples 20 or 21, further comprising an amplitude detector to receive the separated pilot signal from the signal separator and determine an amplitude of the separated pilot signal, and the second output allows the test and measurement accessory to send the amplitude to the test and measurement instrument.

Example 22 is the test and measurement instrument accessory of Example 21, further comprising an analog-to-digital converter coupled to the amplitude detector to digitize the amplitude prior to the second output.

Example 23 is the test and measurement accessory of any of Examples 19 through 22, wherein the output sends the combined electrical signal to the test and measurement instrument.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement accessory, comprising:
an input to receive an input electrical signal from a device under test (DUT);
a pilot signal generator to generate a pilot signal;
an electrical to optical (E/O) converter coupled to the input and the pilot signal generator to convert the input electrical signal and the pilot signal to a combined optical signal;
a fiber to transmit the combined optical signal;
an optical to electrical (O/E) converter to receive the combined optical signal and convert the combined optical signal to a combined electrical signal;
a signal separator to separate the pilot signal from the combined electrical signal;
an amplitude detector to receive the separated pilot signal from the signal separator and determine an amplitude of the separated pilot signal; and
circuitry to adjust a gain of a signal path from the input to a test and measurement instrument using the amplitude of the separated pilot signal.

2. The test and measurement accessory as claimed in claim 1, wherein the pilot signal generator produces an out-of-band pilot signal.

3. The test and measurement accessory as claimed in claim 2, wherein the signal separator comprises a diplexer to separate the out-of-band pilot signal from the combined electrical signal.

4. The test and measurement accessory as claimed in claim 1, wherein the pilot signal comprises a pseudo-random sequence.

5. The test and measurement accessory as claimed in claim 4, further comprising: a second signal generator to generate a matching pseudo-random sequence; and circuitry configured to determine a correlation between the combined electrical signal and the matching pseudo-random sequence.

6. The test and measurement accessory as claimed in claim 1, wherein the E/O converter modulates the input electrical signal onto a carrier signal distinct from the pilot signal.

7. The test and measurement accessory as claimed in claim 1, wherein the pilot signal generator and the E/O converter reside on a first photonics substrate, and the O/E converter, the signal separator, and the amplitude detector reside on a second photonics substrate, the first and second photonics substrates being optically coupled by the fiber.

8. The test and measurement accessory as claimed in claim 1, wherein the circuitry to adjust the gain of the signal path from the input to the test and measurement instrument transmits a signal based upon the amplitude of the separated pilot signal back to the E/O converter.

9. The test and measurement accessory as claimed in claim 1, wherein the circuitry to adjust the gain of the signal path from the input to the test and measurement instrument transmits a signal based upon the amplitude of the separated pilot signal back to the O/E converter.

10. The test and measurement accessory as claimed in claim 1, wherein the circuitry to adjust the gain of the signal path from the input to the test and measurement instrument transmits a signal based upon the amplitude of the separated pilot signal back to an input amplifier electrically coupled to the input.

11. The test and measurement accessory as claimed in claim 1, wherein the circuitry to adjust the gain of the signal path from the input to the test and measurement instrument transmits a signal based upon the amplitude of the separated pilot signal forward to an output amplifier.

12. The test and measurement accessory as claimed in claim 1, wherein the signal separator is structured to produce the separated pilot signal and an output electrical signal.

13. The test and measurement accessory as claimed in claim 12, further comprising an output to send the output electrical signal to the test and measurement instrument.

14. A test and measurement accessory, comprising:
an input to receive an electrical signal from a device under test (DUT);
an electrical to optical (E/O) converter coupled to the input to convert the electrical signal to an optical signal;
an optical splitter separate from the E/O converter to split the optical signal into a feedback portion of the optical signal and a remaining portion of the optical signal;
a fiber to transmit the remaining portion of the optical signal;
a feedback photodiode to generate a feedback signal from the feedback portion of the optical signal and produce a feedback electrical signal to the E/O converter to adjust the optical signal; and
an O/E converter to receive the remaining portion of the optical signal to convert the remaining portion of the optical signal to an electrical signal.

15. The test and measurement accessory as claimed in claim 14, wherein the optical splitter resides on a probe head with the E/O and the input.

16. The test and measurement accessory as claimed in claim 14, wherein the optical splitter resides with the O/E converter, and the test and measurement accessory further comprises a second optical fiber to route the feedback portion back to a probe head containing the E/O and the input.

17. The test and measurement accessory as claimed in claim 14, wherein the E/O converter receives the feedback signal through an amplifier to adjust an output of the amplifier based upon the feedback portion.

18. The test and measurement accessory as claimed in claim 14, wherein the E/O converter receives the feedback signal to adjust the operation of the E/O converter.

19. A test and measurement accessory, comprising:
an input to receive an input electrical signal from a device under test (DUT);
a pilot signal generator to generate a pilot signal;
an electrical to optical (E/O) converter coupled to the input and the pilot signal generator to convert the input electrical signal and the pilot signal to a combined optical signal;
a fiber to transmit the combined optical signal;
an optical to electrical (O/E) converter to receive the combined optical signal and convert the combined optical signal to a combined electrical signal comprised of the pilot signal and an output electrical signal; and
an output to send at least the output electrical signal to a test and measurement instrument.

20. The test and measurement accessory as claimed in claim 19, further comprising a signal separator to separate the combined electrical signal into the output electrical signal and the pilot signal, and a second output to allow the test and measurement accessory to send the pilot signal to the test and measurement instrument.

21. The test and measurement accessory as claimed in claim 20, further comprising an amplitude detector to receive the separated pilot signal from the signal separator and determine an amplitude of the separated pilot signal, and the second output allows the test and measurement accessory to send the amplitude to the test and measurement instrument.

22. The test and measurement instrument accessory as claimed in claim 21, further comprising an analog-to-digital converter coupled to the amplitude detector to digitize the amplitude prior to the second output.

23. The test and measurement accessory as claimed in claim 19, wherein the output sends the combined electrical signal to the test and measurement instrument.
